(19) United States
(12) Patent Application Publication
(10) Pub. No.: US 2026/0214971 A1
(43) Pub. Date: Jul. 23, 2026

(54) VOLTAGE-TUNABLE POLYSILICON RESISTOR AND OPERATION METHOD THEREOF

(71) Applicant: Winbond Electronics Corp., Taichung City (TW)

(72) Inventors: Chao-Lung Wang, Taichung City (TW); Kuan-Yu Lin, Taichung City (TW)

(73) Assignee: Winbond Electronics Corp., Taichung City (TW)

(21) Appl. No.: 19/409,687

(22) Filed: Dec. 4, 2025

(30) Foreign Application Priority Data
Jan. 22, 2025 (TW) 114102849

(51) Int. Cl. H10D 84/00; H10D 1/47; H10D 62/10

(52) U.S. Cl. CPC H10D 84/209; H10D 1/47; H10D 62/102

(57) ABSTRACT

Provided is a voltage-tunable polysilicon resistor, which includes a semiconductor substrate, a device isolation structure, at least one polysilicon resistor structure, a polysilicon control layer and a dielectric layer. The device isolation structure is disposed in the semiconductor substrate to define an active region. The polysilicon resistor structure is disposed on the active region. The polysilicon control layer is disposed on the polysilicon resistor structure, and the polysilicon control layer is coupled to a control voltage source to modulate a resistance value of the polysilicon resistor structure. The dielectric layer is disposed between the polysilicon control layer and the polysilicon resistor structure.

### CROSS-REFERENCE TO RELATED APPLICATION

This application claims the priority benefit of Taiwan application serial no. 114102849, filed on January 22, 2025. The entirety of the foregoing-mentioned patent application is hereby incorporated by reference herein and made a part of this specification.

### BACKGROUND

### Technical Field

The disclosure relates to a semiconductor resistor technology, and in particular relates to a voltage-tunable polysilicon resistor and an operation method thereof.

### Related Art

CMOS integrated circuits typically use polysilicon to manufacture on chip resistors. However, when a resistance needed is high, such as a high-resistance device of KΩ to GΩ, a considerably large layout area on a chip may need to be occupied.

### SUMMARY

The disclosure provides a voltage-tunable polysilicon resistor, which can effectively achieve a high-resistance device in a limited layout space.

The disclosure further provides an operation method of the voltage-tunable polysilicon resistor, which can change a resistance value of the resistor through a voltage.

The voltage-tunable polysilicon resistor of the disclosure includes a semiconductor substrate, a device isolation structure, at least one polysilicon resistor structure, a polysilicon control layer, and a dielectric layer. The device isolation structure is disposed in the semiconductor substrate to define an active region. The at least one polysilicon resistor structure is disposed on the active region. The polysilicon control layer is disposed on the at least one polysilicon resistor structure, and coupled to a control voltage source to modulate a resistance value of the at least one polysilicon resistor structure. The dielectric layer is disposed between the polysilicon control layer and the at least one polysilicon resistor structure.

In an embodiment of the disclosure, the device isolation structure and the at least one polysilicon resistor structure extend along a first direction, the polysilicon control layer extends along a second direction, and the second direction is different from the first direction.

In an embodiment of the disclosure, the dielectric layer includes a silicon oxide layer, a silicon nitride layer, a high dielectric constant (high-k) material layer or an oxide-nitride-oxide (ONO) structure.

In an embodiment of the disclosure, a quantity of the at least one polysilicon resistor structure is multiple polysilicon resistor structures, and the polysilicon control layer extends on the dielectric layer between the multiple polysilicon resistor structures.

In an embodiment of the disclosure, a bottom surface of the polysilicon control layer is lower than a top surface of the multiple polysilicon resistor structures.

In an embodiment of the disclosure, the voltage-tunable polysilicon resistor further includes multiple first contact windows directly contacting the polysilicon control layer to couple the polysilicon control layer to the control voltage source through the multiple first contact windows.

In an embodiment of the disclosure, the voltage-tunable polysilicon resistor further includes multiple second contact windows, respectively contacting both ends of the polysilicon resistor structure.

According to the operation method of the voltage-tunable polysilicon resistor of the disclosure, the voltage-tunable polysilicon resistor includes a semiconductor substrate having a device isolation structure and an active region defined by the device isolation structure, a polysilicon resistor structure disposed on the active region, a dielectric layer disposed on the polysilicon resistor structure, and a polysilicon control layer disposed on the dielectric layer and covering the polysilicon resistor structure. The operation method includes coupling a first end of the polysilicon resistor structure to a first node, coupling a second end of the polysilicon resistor structure to a second node, and applying a control voltage to the polysilicon control layer to modulate a resistance value of the polysilicon resistor structure.

In another embodiment of the disclosure, a greater the control voltage, a greater the resistance value of the polysilicon resistor structure.

In another embodiment of the disclosure, the resistance value of the polysilicon resistor structure is a resistance value between the first node and the second node.

In another embodiment of the disclosure, the resistance value of the polysilicon resistor structure is increased by 10 times to 10⁸ times before and after the control voltage is applied.

Based on the above, the voltage-tunable polysilicon resistor of the disclosure may utilize a voltage modulation to implement a high-resistance operation application through a combination of the polysilicon resistor structure and the polysilicon control layer, thereby effectively achieving a high-resistance device in a limited layout space. Moreover, the voltage-tunable polysilicon resistor of the disclosure may be integrated with an existing flash process, thereby reducing the process cost and complexity.

In order to make the features and advantages of the disclosure more comprehensible, the following examples are given and described in detail with the accompanying drawings as follows.

### BRIEF DESCRIPTION OF THE DRAWINGS

FIG. 1 is a top view of a voltage-tunable polysilicon resistor according to an embodiment of the disclosure.

FIG. 2 is a cross-sectional view of the voltage-tunable polysilicon resistor along the line II-II’ in FIG. 1.

FIG. 3 is a cross-sectional view of the voltage-tunable polysilicon resistor along the line III-III’ in FIG. 1.

FIG. 4A is an operational schematic view of a voltage-tunable polysilicon resistor according to another embodiment of the disclosure.

FIG. 4B is an equivalent circuit diagram of the voltage-tunable polysilicon resistor in FIG. 4A.

FIG. 5 is a current-voltage (I-V) curve graph of a voltage-tunable polysilicon resistor according to some embodiments of the disclosure.

FIG. 6 is a resistance-voltage (R-V) curve graph of a voltage-tunable polysilicon resistor according to some embodiments of the disclosure.

FIG. 7A to FIG. 7C are cross-sectional views corresponding to a process flow of a voltage-tunable polysilicon resistor according to yet another embodiment of the disclosure.

### DESCRIPTION OF THE EMBODIMENTS

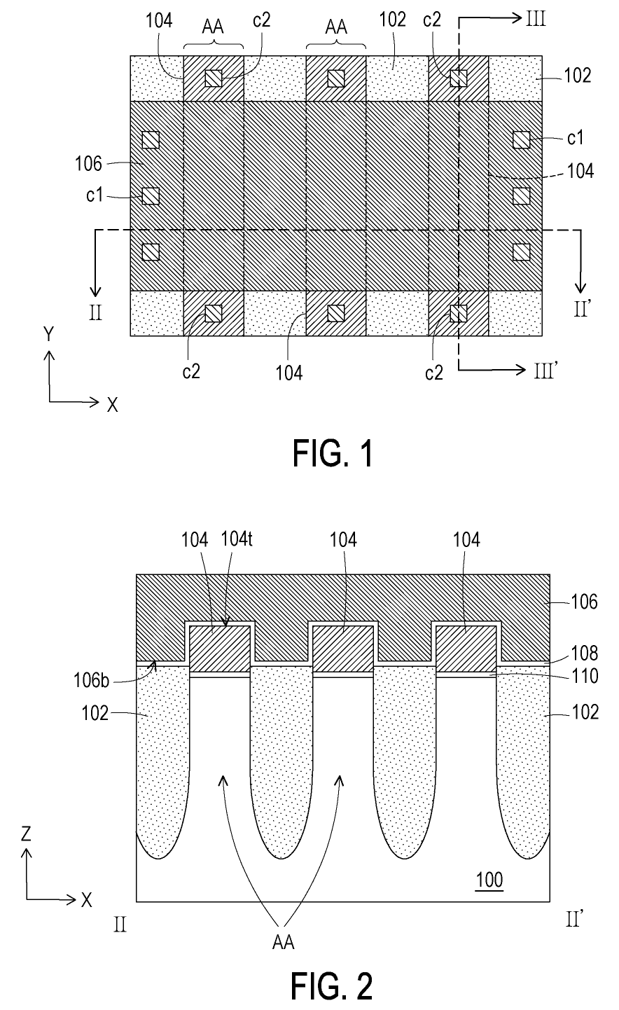

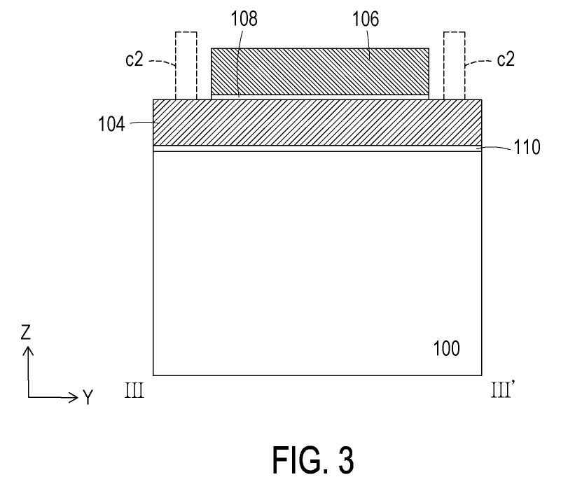

FIG. 1 is a top view of a voltage-tunable polysilicon resistor according to an embodiment of the disclosure. FIG. 2 is a cross-sectional view of the voltage-tunable polysilicon resistor along the line II-II’ in FIG. 1. FIG. 3 is a cross-sectional view of the voltage-tunable polysilicon resistor along the line III-III’ in FIG. 1.

Please refer to FIG. 1, FIG. 2 and FIG. 3. The voltage-tunable polysilicon resistor of the embodiment at least includes a semiconductor substrate 100, a device isolation structure 102, a polysilicon resistor structure 104, a polysilicon control layer 106, and a dielectric layer 108. The semiconductor substrate 100 is, for example, a silicon substrate or other appropriate semiconductor substrates. The device isolation structure 102 is disposed in the semiconductor substrate 100 to define an active region AA. The device isolation structure 102 is, for example but not limited to, a shallow trench isolation (STI), a deep trench isolation (DTI), etc. The polysilicon resistor structure 104 is disposed on the active region AA. FIG. 1 and FIG. 2 show 3 polysilicon resistor structures 104, but the disclosure is not limited thereto. In other embodiments, a quantity of the polysilicon resistor structures 104 may be one, two, or more than 3. Additionally, an insulation layer 110 may be disposed between the semiconductor substrate 100 and the polysilicon resistor structure 104. The insulation layer 110 is, for example but not limited to, a silicon oxide layer or other insulating material layers.

Please refer to FIG. 2 and FIG. 3 again. The polysilicon control layer 106 is disposed on the polysilicon resistor structure 104. The dielectric layer 108 is disposed between the polysilicon control layer 106 and the polysilicon resistor structure 104. In some embodiments, the dielectric layer 108 is, for example but not limited to, a silicon oxide layer, a silicon nitride layer, a high dielectric constant (high-k) material layer, or an oxide-nitride-oxide (ONO) structure. The dielectric layer 108 may be conformal with the polysilicon resistor structure 104 and the device isolation structure 102, so the polysilicon control layer 106 covering the dielectric layer 108 may fill a space between the adjacent polysilicon resistor structure 104 to allow a bottom surface 106b of the polysilicon control layer 106 to be lower than a top surface 104t of the polysilicon resistor structure 104. This structure may facilitate a control of an electric field of the polysilicon resistor structure 104, thereby more efficiently utilizing a voltage to modulate a resistance value of the polysilicon resistor structure 104. The polysilicon control layer 106 is coupled to a control voltage source (not shown) to modulate the resistance value of the polysilicon resistor structure 104.

In FIG. 1, the device isolation structure 102 and the polysilicon resistor structure 104 extend along a Y direction (also referred to as a “first direction”). That is to say, the device isolation structure 102 is disposed in the semiconductor substrate 100 along the Y direction, and thereby defining the active region AA extending along the Y direction. The polysilicon resistor structure 104 is formed on the active region AA, thus also extending along the Y direction. In the embodiment, the polysilicon resistor structure 104 is a strip structure extending along the Y direction. The polysilicon control layer 106 may extend along an X direction (also referred to as a “second direction”), that is, the polysilicon resistor structure 104 and the polysilicon control layer 106 extend in different directions, but the disclosure is not limited thereto. In other embodiments, the polysilicon control layer 106 may extend along the Y direction and be disposed on top of the polysilicon resistor structure 104. In the embodiment, the voltage-tunable polysilicon resistor may further include multiple first contact windows c1, directly contacting the polysilicon control layer 106, to couple the polysilicon control layer 106 to the control voltage source through the first contact windows c1. In FIG. 1 and FIG. 3, the voltage-tunable polysilicon resistor may further include multiple second contact windows c2, respectively contacting both ends of the polysilicon resistor structure 104. The resistance value of the polysilicon resistor structure 104 is approximately a resistance value obtained between the second contact windows c2 at the both ends of the polysilicon resistor structure 104.

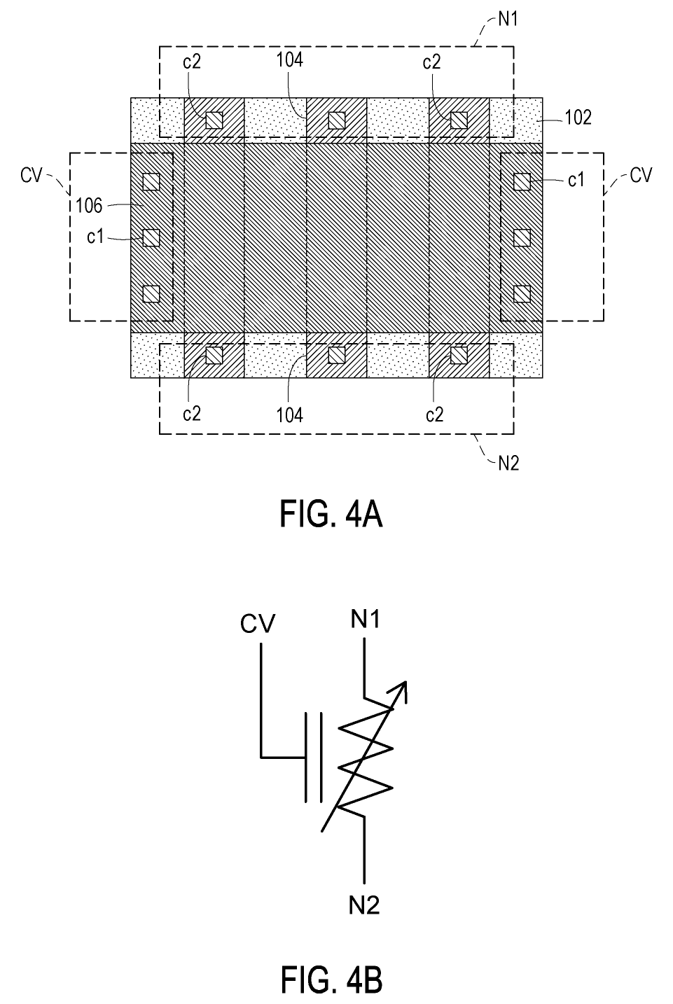

FIG. 4A is an operational schematic diagram of a voltage-tunable polysilicon resistor according to another embodiment of the disclosure. The same reference numerals as in the previous embodiment are used to represent the same or similar parts and components, and the relevant content of the same or similar parts and components may also refer to the content of the previous embodiment, which will not be repeated here. FIG. 4B is an equivalent circuit diagram of the voltage-tunable polysilicon resistor in FIG. 4A.

Please refer to FIG. 4A and FIG. 4B. An operation method of the embodiment is for the voltage-tunable polysilicon resistor of the previous embodiment, but the disclosure is not limited thereto. The operation method of the embodiment may also be implemented in other polysilicon resistors, but essentially needs a polysilicon resistor structure disposed on an active region, a dielectric layer disposed on the polysilicon resistor structure, and a polysilicon control layer disposed on the dielectric layer and covering the foregoing polysilicon resistor structure.

The operation method of the embodiment includes coupling a first end of the polysilicon resistor structure 104 to a first node N1, coupling a second end of the polysilicon resistor structure 104 to a second node N2, and applying a control voltage CV to the polysilicon control layer 106 to modulate the resistance value of the polysilicon resistor structure 104. FIG. 4A shows 3 polysilicon resistor structures 104, so one end of the 3 polysilicon resistor structures 104 may be connected to the first node N1 using the second contact windows c2, and the other end of the 3 polysilicon resistor structures 104 may be connected to the second node N2 using the second contact windows c2. That is to say, the multiple polysilicon resistor structures 104 in the figure are respectively coupled to the first node N1 and the second node N2 in parallel. Therefore, the resistance value of the polysilicon resistor structure 104 refers to a resistance value between the first node N1 and the second node N2. The control voltage CV may be applied through the first contact windows c1 on either side of the polysilicon control layer 106, for example, from the first contact windows c1 on a left side of the figure, or from the first contact windows c1 on a right side of the figure.

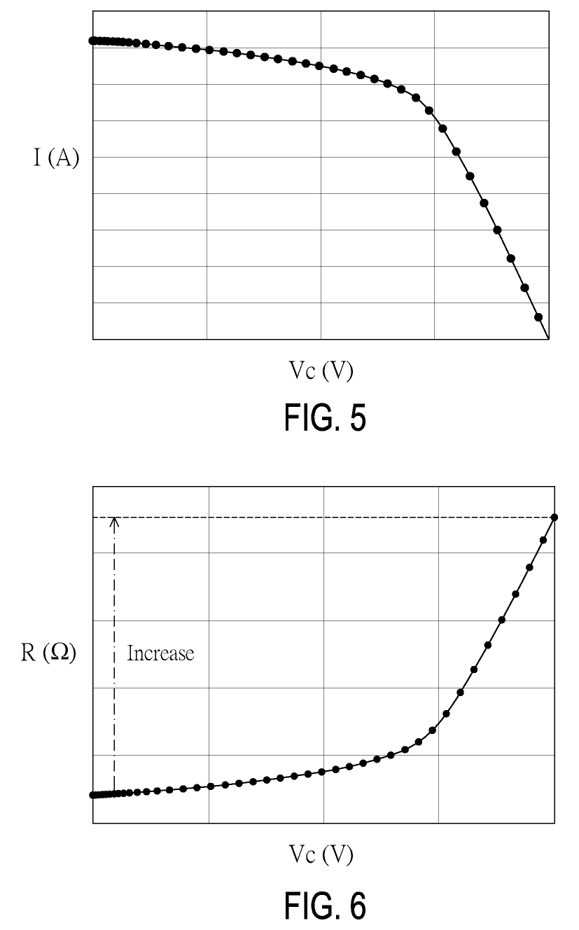

Through a TCAD simulation of the foregoing voltage-tunable polysilicon resistor, a current-voltage (I-V) curve graph as shown in FIG. 5 may be obtained. A current in the polysilicon resistor structure 104 is shown to be decreased as a voltage (Vc) applied to the polysilicon control layer 106 is increased, so it may be obtained that an electric field of the polysilicon control layer 106 may control the current in the polysilicon resistor structure 104. Then, based on the I-V curve graph, a resistance-voltage (R-V) curve graph in FIG. 6 is derived, and a result may be obtained from FIG. 6 that a higher the voltage applied to the polysilicon control layer 106, a higher the resistance value (R). Therefore, the higher the control voltage in the voltage-tunable polysilicon resistor of the disclosure, the higher the resistance value of the polysilicon resistor structure 104. Moreover, based on the result of the foregoing simulation, it may be obtained that the resistance value of the polysilicon resistor structure may be increased by more than 10 times before and after the control voltage is applied, for example, increased by more than 10² times, increased by more than 10³ times, increased by more than 10⁴ times, increased by more than 10⁵ times, or even increased up to 10⁸ times. Therefore, the voltage-tunable polysilicon resistor of the disclosure may achieve a high-resistance operation application (such as an operation application from KΩ to GΩ).

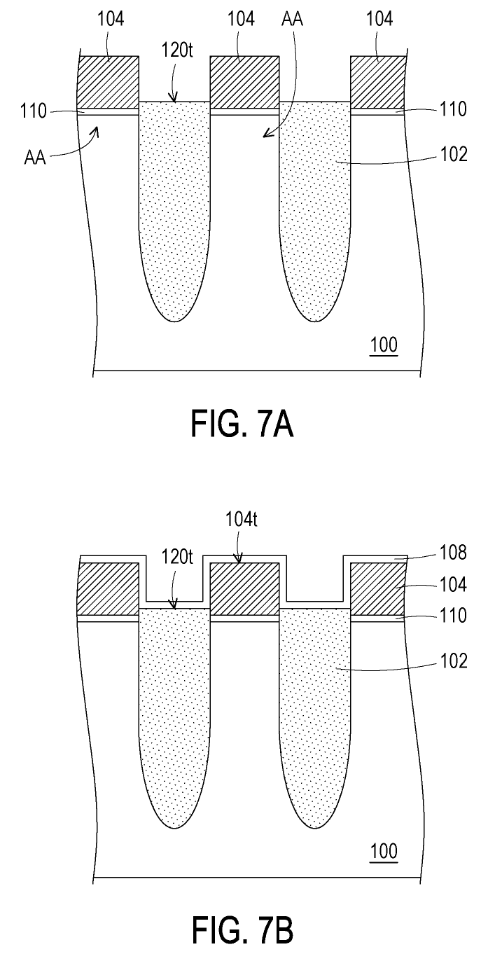

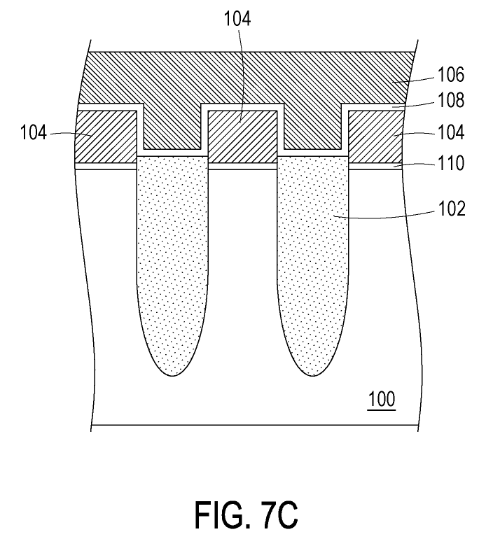

FIG. 7A to FIG. 7C are cross-sectional views corresponding to a process flow for a voltage-tunable polysilicon resistor according to yet another embodiment of the disclosure. The same reference numerals as in FIG. 2 are used to represent the same or similar parts and components, and the related content of the same or similar parts and components may also refer to the related content of FIG. 2, which will not be repeated here.

In FIG. 7A, the device isolation structure 102 may first be formed in the semiconductor substrate 100 to define the active region AA. A method of forming the device isolation structure 102 is, for example but not limited to, utilizing photolithography and etching processes to form trenches in the semiconductor substrate 100, and then depositing insulating materials such as oxide in the trenches. Then, the insulation layer 110 and the polysilicon resistor structure 104 are formed on the active region AA. Moreover, the steps may also be integrated with an existing flash process. For example, the insulation layer 110 may be formed using the same method as forming a gate insulation layer, and then the polysilicon resistor structure 104 may be formed using the same method as forming a floating gate. In addition, the device isolation structure 102 may also be formed after the insulation layer 110 and the polysilicon resistor structure 104 are formed to allow a top surface 102t of the device isolation structure 102 to be slightly higher than the insulation layer 110, but the disclosure is not limited thereto.

Next, please refer to FIG. 7B. The dielectric layer 108 is conformally deposited on the polysilicon resistor structure 104 and the device isolation structure 102 to allow the dielectric layer 108 to cover the top surface 102t of the device isolation structure 102, the top surface 104t and side surfaces 104s of the polysilicon resistor structure 104. Moreover, this step may also be integrated with the existing flash process. For example, the dielectric layer 108 may be formed using the same method as forming an inter-gate dielectric layer.

Subsequently, please refer to FIG. 7C. The polysilicon control layer 106 covering the polysilicon resistor structure 104 is deposited on top of the dielectric layer 108. Moreover, this step may also be integrated with the existing flash process. For example, the polysilicon control layer 106 may be formed using the same method as forming a control gate.

In summary, the voltage-tunable polysilicon resistor of the disclosure may utilize a voltage modulation to implement the high-resistance operation application through a combination of the polysilicon resistor structure and the polysilicon control layer, thereby effectively achieving a high-resistance device (such as ~KΩ to GΩ) in a limited layout space. Moreover, the voltage-tunable polysilicon resistor of the disclosure may be integrated with the existing flash process, thereby reducing the process cost and complexity.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A voltage-tunable polysilicon resistor, comprising:
a semiconductor substrate;
a device isolation structure, disposed in the semiconductor substrate, to define an active region;
at least one polysilicon resistor structure, disposed on the active region;
a polysilicon control layer, disposed on the at least one polysilicon resistor structure, and coupled to a control voltage source to modulate a resistance value of the at least one polysilicon resistor structure; and
a dielectric layer, disposed between the polysilicon control layer and the at least one polysilicon resistor structure.

2. The voltage-tunable polysilicon resistor according to claim 1, wherein the device isolation structure and the at least one polysilicon resistor structure extend along a first direction, the polysilicon control layer extends along a second direction, and the second direction is different from the first direction.

3. The voltage-tunable polysilicon resistor according to claim 1, wherein the dielectric layer comprises a silicon oxide layer, a silicon nitride layer, a high dielectric constant (high-k) material layer or an oxide-nitride-oxide (ONO) structure.

4. The voltage-tunable polysilicon resistor according to claim 1, wherein a quantity of the at least one polysilicon resistor structure is a plurality of polysilicon resistor structures, and the polysilicon control layer extends on the dielectric layer between the plurality of polysilicon resistor structures.

5. The voltage-tunable polysilicon resistor according to claim 4, wherein a bottom surface of the polysilicon control layer is lower than a top surface of the plurality of polysilicon resistor structures.

6. The voltage-tunable polysilicon resistor according to claim 1, further comprising a plurality of first contact windows directly contacting the polysilicon control layer to couple the polysilicon control layer to the control voltage source through the plurality of first contact windows.

7. The voltage-tunable polysilicon resistor according to claim 1, further comprising a plurality of second contact windows, respectively contacting both ends of the polysilicon resistor structure.

8. An operation method of a voltage-tunable polysilicon resistor, wherein the voltage-tunable polysilicon resistor comprises a semiconductor substrate having a device isolation structure and an active region defined by the device isolation structure, a polysilicon resistor structure disposed on the active region, a dielectric layer disposed on the polysilicon resistor structure, and a polysilicon control layer disposed on the dielectric layer and covering the polysilicon resistor structure, and the operation method comprises:
coupling a first end of the polysilicon resistor structure to a first node;
coupling a second end of the polysilicon resistor structure to a second node; and
applying a control voltage to the polysilicon control layer to modulate a resistance value of the polysilicon resistor structure.

9. The operation method of the voltage-tunable polysilicon resistor according to claim 8, wherein a greater the control voltage, a greater the resistance value of the polysilicon resistor structure.

10. The operation method of the voltage-tunable polysilicon resistor according to claim 8, wherein the resistance value of the polysilicon resistor structure is a resistance value between the first node and the second node.

11. The operation method of the voltage-tunable polysilicon resistor according to claim 8, wherein the resistance value of the polysilicon resistor structure is increased by 10 times to 10⁸ times before and after the control voltage is applied.
